(19) United States
(12) Patent Application Publication
(10) Pub. No.: US 2017/0153033 A1
(43) Pub. Date: Jun. 1, 2017

(54) Measuring System of Heat Load in Perimeter Zone and Air-Conditioning Control System

(71) Applicant: Hitachi, Ltd., Chiyoda-ku, Tokyo (JP)

(72) Inventors: Naoki YOSHIMOTO, Tokyo (JP); Masahiko ANDO, Tokyo (JP)

(21) Appl. No.: 15/309,607

(22) PCT Filed: Apr. 8, 2015
(86) PCT No.: PCT/JP2015/060902

§ 371 Date: Nov. 8, 2016

(30) Foreign Application Priority Data
May 21, 2014 (JP) 2014-104825

(51) Int. Cl. F24F 11/00; H02S 50/00; H02S 20/26; G05B 19/048; H01L 31/0468

(52) U.S. Cl. CPC F24F 11/006; F24F 11/0012; F24F 11/0034; F24F 11/0015; G05B 19/048; H01L 31/0468; H02S 20/26; H02S 50/00; F24F 2011/0049; F24F 2221/20; F24F 2011/0036; F24F 2011/0038; G05B 2219/2614

(57) ABSTRACT

An object of the invention is to provide an estimating system of heat load in a perimeter zone which can detect heat load in a perimeter zone with high accuracy without providing an exclusive detecting device for detecting heat load, such as a radiation thermometer. The estimating system of heat load in a perimeter zone in the invention includes a light-transmitting solar cell which is provided on a window face; and heat load estimating means for estimating heat load in a perimeter zone based on output characteristics of the solar cell, in which the heat load estimating means obtains an intensity of solar radiation from a window face and a temperature of the solar cell, from a short circuit current value and an open voltage value due to power generation of the solar cell, and calculates a mean radiant temperature in the perimeter zone using the intensity of solar radiation and the temperature of the solar cell.

### TECHNICAL FIELD

The present invention relates to a system in which a light-transmitting solar light power generation system is introduced in a perimeter zone, and relative heat load in the perimeter zone is measured by using a power generation parameter thereof.

### BACKGROUND ART

In recent years, overpopulation in a city is deepened, and as a result, energy consumption also increases along with Manhattanizing of a building. In a building including an office building, promoting of energy saving is desired. Since most of energy in an office building which is an example of a high-rise building is consumed in air-conditioning, a technology which contributes to energy saving in air-conditioning is taken into consideration. Vicinity of a window side, that is, a perimeter zone particularly has a major influence on a load of air-conditioning, relating to an energy-saving technology in air-conditioning of an office building. In particular, solar radiation enters in the vicinity of a window, and as a result, since heat load occurs in objects in the vicinity of the window, and radiant heat is generated, it becomes a large heat load with respect to air-conditioning. In addition, since a window material has a large heat transmission coefficient compared to a wall material, comings and goings of heat with outside air also becomes frequent compared to the vicinity of wall.

In this manner, reducing of heat load in a perimeter zone of a building can remarkably contribute to reducing in power consumption of air-conditioning. For this reason, it is important to reduce an energy loss of air-conditioning by detecting heat load in a perimeter zone with good accuracy.

Relating to detecting of heat load, a system in which a perimeter zone in the vicinity of a window is monitored by a radiation thermometer, the heat load in the entire perimeter zone is directly measured by the radiation thermometer to be used in an air-conditioning control has been proposed in PTL 1. Since heat load of the entire perimeter zone is directly measured by the radiation thermometer, an excellent detecting accuracy is obtained. Meanwhile, it is necessary to provide an exclusive device for detecting heat load in each perimeter zone, and there is a problem of a rise in cost for the device, or installing of the device.

A method of estimating an intensity of solar radiation which is input to the inside of a room using a calculation, based on information of a solar position, an incident angle of sunlight, or the like, and information of an intensity of solar radiation, or the like, which is detected by a solar radiation intensity detecting device which is provided in a rooftop, and estimating a temperature of a commodity to be irradiated, and a mean radiant temperature, using a calculation based on the estimated intensity of solar radiation has been proposed in PTL 2.

### CITATION LIST

### Patent Literature

PTL 1: JP-A-8-94148

PTL 2: JP-A-2013-57476

### SUMMARY OF INVENTION

### Technical Problem

According to the method in PTL 2, it is not necessary to provide an exclusive device for detecting heat load in each perimeter zone, and it is effective in reducing cost. Meanwhile, since information of a solar position, an incident angle of sunlight, or the like, and an intensity of solar radiation, or the like, which is detected by the solar radiation intensity detecting device provided in a rooftop are obtained by not directly measuring information of a perimeter zone, and are indirect pieces of information, there is room for an improvement in detecting accuracy of heat load.

An object of the invention is to provide an estimating system of heat load in a perimeter zone which can detect heat load in a perimeter zone with high accuracy, without providing an exclusive detecting device for detecting heat load such as a radiation thermometer.

### Solution to Problem

An estimating system of heat load in a perimeter zone in the invention includes a light-transmitting solar cell which is provide on a window face, and heat load estimating means for estimating heat load in a perimeter zone based on a power generation parameter of the solar cell, in which the heat load estimating means obtains an intensity of solar radiation from a window face and a temperature of the solar cell from a short circuit current value and an open voltage value due to power generation of the solar cell, and calculates a mean radiant temperature in a perimeter zone, using the intensity of solar radiation and the temperature of the solar cell.

### Advantageous Effects of Invention

According to the invention, it is possible to provide an estimating system of heat load in a perimeter zone which can detect heat load in a perimeter zone with high accuracy, without providing an exclusive detecting device for detecting heat load such as a radiation thermometer.

### BRIEF DESCRIPTION OF DRAWINGS

FIG. 1 is an example of a functional block diagram which describes a first embodiment.

FIG. 2 is an example of a schematic diagram of an organic thin film solar cell which is provided at a window opening portion in the first embodiment.

FIG. 3 is an example of a flowchart which illustrates an operation procedure of a system which describes the first embodiment.

FIG. 4 is an example of a calibration curve which illustrates a relationship between a short circuit current value of the organic thin film solar cell and an intensity of solar radiation in the first embodiment.

FIG. 5 is an example of a calibration curve which illustrates a relationship between a temperature and an open voltage value of the organic thin film solar cell in the first embodiment.

FIG. 6 is an example of a functional block diagram which describes a second embodiment.

FIG. 7 is an example of a flowchart which illustrates an operation procedure of a system which describes the second embodiment.

FIG. 8 is a diagram which illustrates a measurement result of an example and a reference example.

FIG. 9 is a diagram which illustrates a result of a PMV value which is calculated in the example.

### DESCRIPTION OF EMBODIMENTS

Hereinafter, embodiments for performing the invention will be described. The following embodiments are examples, and the invention is not limited by the embodiments at all.

In the embodiment, it is possible to successively detect an intensity of solar radiation which is input to an window opening portion, and a temperature of a light-transmitting organic thin film solar cell (temperature on window face), by providing the light-transmitting organic thin film solar cell at the window opening portion, and detecting output characteristics (power generation data) of the organic thin film solar cell. In addition, it is possible to estimate a mean radiant temperature in a perimeter zone based on the intensity of solar radiation and the temperature on the window face. It is possible to perform a successive control of air-conditioning using data based on power generation data of the organic thin film solar cell, an indoor temperature, and an indoor humidity. Since the organic thin film solar cell is provided on a window face as a perimeter zone, it is possible to perform a highly accurate detection of heat load, by detecting an intensity of solar radiation and a temperature on a window face, using the power generation data. In addition, since the organic thin film solar cell also has a function of generating energy due to power generation, the organic thin film solar cell is not provided only for detecting heat load. In addition, it is also possible to obtain an energy saving effect due to a heat shutting-off effect of solar radiation on a window face, by providing the light-transmitting solar cell on the window face.

Hereinafter, the embodiment of the invention will be described in detail; however, the invention is not limited at all, only by the following embodiment.

### First Embodiment

An intensity of solar radiation which is input to a window opening portion and a temperature on a window face are detected by providing a light-transmitting organic thin film solar cell at the window opening portion, and detecting power generation data of the organic thin film solar cell. Since a window side zone (perimeter zone) is in contact with a window face of which a heat transmission coefficient is several times of that of a wall face, comings and goings of an indoor temperature with outside air becomes frequent, and solar radiation is input. In addition, due to a temperature rise in a commodity around the window side, or in a light shading tool such as a blind due to solar radiation, a mean radiant temperature derived from radiant heat which is radiated from the commodity rises, as a result. When it is possible to detect heat load in a perimeter zone, that is, the mean radiant temperature, it is possible to contribute to an air-conditioning control of the perimeter zone. In addition, when requesting a predicted mean vote (PMV) which is adopted as a standard thermal index in which a parameter of a human body detection environment is taken in, it is possible to perform an air-conditioning control in which the human body detection environment is reflected.

In a first embodiment, outlines of an estimating system of heat load in a perimeter zone in which the organic thin film solar cell is provided in a window opening portion, and an air-conditioning control system will be described with reference to drawings. The embodiment is an example, and is not limited at all, when performing the invention.

(Configuration of System)

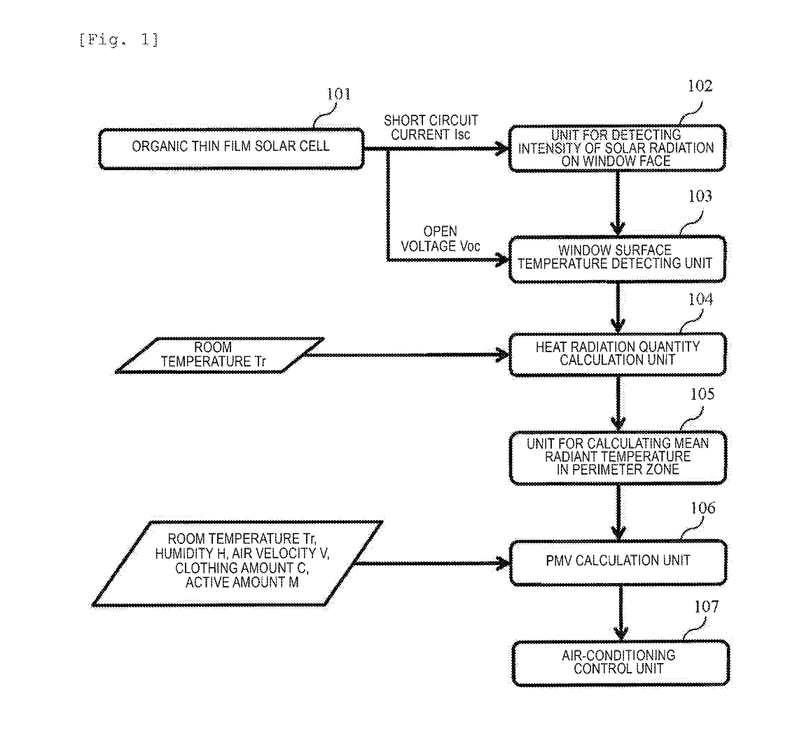

FIG. 1 illustrates a functional block diagram which describes the first embodiment. The estimating system of heat load in a perimeter zone is provided with an organic thin film solar cell 101 which is provided in a window opening portion, and heat load estimating means for estimating heat load which estimates heat load in a perimeter zone, based on output characteristics of the organic thin film solar cell 101. The heat load estimating means is configured of a unit 102 for detecting an intensity of solar radiation on a window face which calculates an intensity of solar radiation on a window face from a short circuit current of the organic thin film solar cell, a window surface temperature detecting unit 103 which calculates a window face temperature from the intensity of solar radiation which is calculated by the unit for detecting an intensity of solar radiation on a window face, and an open voltage of the organic thin film solar cell, a heat radiation quantity calculation unit 104 which calculates a heat radiation quantity due to convection and radiation from the window face temperature, and a mean radiant temperature calculation unit 105 which calculates a mean radiant temperature from the calculated heat radiation quantity. In addition, as illustrated in FIG. 1, it is possible to perform an air-conditioning control in which the human body detection environment is reflected, by providing a PMV calculation unit 106 which calculates PMV in which the human body detection environment is reflected, using a measured indoor temperature and humidity, an air velocity, a clothing amount, an active amount, and the calculated mean radiant temperature. In addition, it is also possible to perform an air-conditioning control in a perimeter zone using the mean radiant temperature, by omitting the PMV calculation unit 106.

In addition, the air-conditioning control system in the embodiment is configured by further including an air-conditioning control unit 107 which controls air-conditioning in the above described heat load estimating system. The mean radiant temperature which is calculated in the mean radiant temperature calculation unit 105, or PMV which is calculated in the PMV calculation unit 106 is sent to the air-conditioning control unit 107, and a control of an air conditioner is performed by the air-conditioning control unit 107.

(Description of Organic Thin Film Solar Cell)

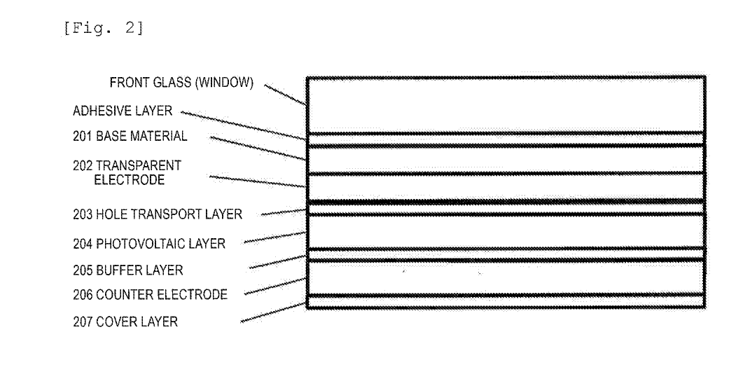

FIG. 2 illustrates a schematic diagram of the organic thin film solar cell which is provided in a window opening portion. In addition, FIG. 2 is a schematic diagram, and dimensions thereof are not limited. The organic thin film solar cell has a light-transmitting property, and is fixed to a window face using bonding, or the like, using an adhesive. A base material 201 of the organic thin film solar cell can be formed in an arbitrary shape such as a plastic plate shape of a transparent film, PET, or PMMA including polyethylene terephthalate (PET), polymethyl methacrylate (PMMA), or the like, which can be easily bonded to the window face, or a glass substrate shape. A transparent electrode 202, a hole transport layer 203, a photovoltaic layer 204, a buffer layer 205, a counter electrode 206, and a cover layer 207 are stacked in this order with respect to the base material 201. The stacking structure is an example, and is not limited at all, as long as the structure has no influence on power generation of the organic thin film solar cell and a system configuration.

The transparent electrode 202 is not particularly limited when the electrode is an arbitrary thin film with a light-transmitting property such as a metal oxide such as ITO, or a PEDOT-PSS electro-conductive high polymer with a large doping amount, and is formed in a range of a film thickness of 100 to 500 nm. The hole transport layer 203 transports a hole of PEDOT-PSS, a nickel oxide, or the like, and in which a thin film which blocks electrons is provided in a range of a film thickness of 5 to 100 nm. The photovoltaic layer 204 is configured, using a bonding structure caused by a phase separation which is referred to as a bulk hetero-j unction layer. A donor molecule is a high polymer such as PCDTT-DPP, and an acceptor molecule is a fullerene derivative, or the like, such as C60-PCBM. The buffer layer 205 is a thin film which transports electrons, and blocks holes, and is obtained by forming a thin film of lithium fluoride, a titanium oxide, or the like, in a film thickness of 1 to 10 nm. The counter electrode 206 can be formed by using a method of depositing a metal oxide including ITO, or metal such as gold or silver, by maintaining a light-transmitting property, or a method of manufacturing an electrode by applying and forming dispersing liquid such as a silver nanowire. The cover layer 207 is provided as a protective layer of the organic thin film solar cell, is provided in order for a safety, and can be manufactured, using a method of laminating a high polymer film of polyester, a copolymer of polyvinyl acetate-polyvinyl alcohol, and the like, with the base material 201.

(Specific Operation Method of System)

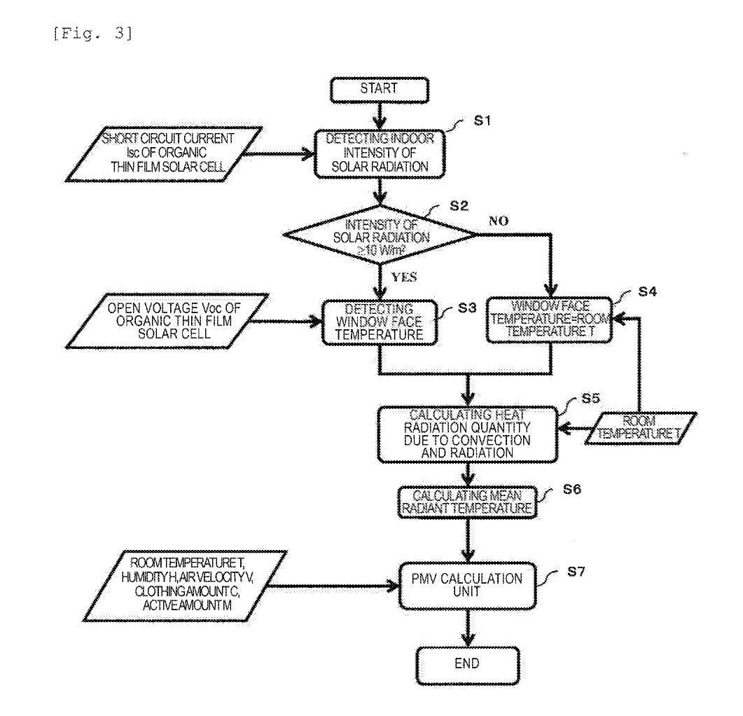

FIG. 3 is a flowchart which illustrates an operation procedure of a system. In addition, items illustrated on the left side in FIG. 3 are input parameters in a series of system operations, and parameters which can be determined in advance according to installation conditions and an indoor environment of a building are illustrated on the right side.

(Detecting of Intensity of Solar Radiation on Window Face)

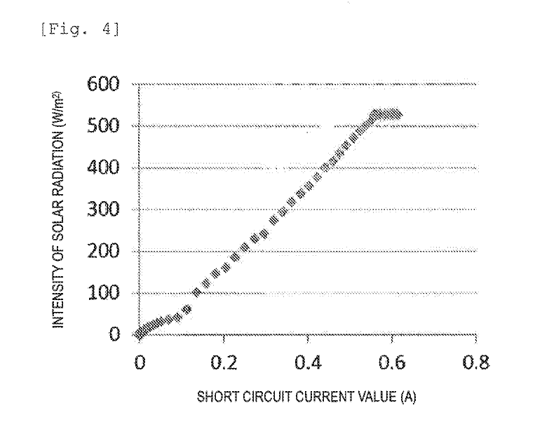

Step S1 is a process for determining an intensity of solar radiation by detecting a short circuit current value of the organic thin film solar cell. FIG. 4 illustrates an example of a result in which a relationship of a short circuit current value Isc with respect to an intensity of solar radiation in the organic thin film solar cell is illustrated. As illustrated in FIG. 4, since the intensity of solar radiation and the short circuit current value Isc are in a linear relationship, it is possible to successively detect an intensity of solar radiation from the short circuit current value, by preparing a calibration curve which is illustrated in FIG. 4 in advance, and it is possible to uniquely determine thereof.

(Detecting of Window Face Temperature)

Subsequently, whether or not the intensity of solar radiation detected in Step S1 is 10 W/m² or more is determined (Step S2). The reason for this is that the short circuit current value Isc is changed according to a temperature T₁ of the organic thin film solar cell. In a case in which the intensity of solar radiation is 10 W/m² or more, since a change in short circuit current value in a use temperature zone is sufficiently small with respect to a change amount which corresponds to an intensity of solar radiation, the process proceeds to detecting of a window face temperature in step S3 using the intensity of solar radiation which is detected in step S1.

Meanwhile, in a case in which the intensity of solar radiation detected in step S1 is less than 10 W/m², the own temperature T₁ of the organic thin film solar cell is temporarily stored as a room temperature Tr (step S4), and the process proceeds to a calculation of a heat radiation quantity due to convection and radiation. The reason for this is that, in a case in which the intensity of solar radiation is less than 10 W/m², a relative value in an increase in current associated with power generation and a temperature rise due to solar radiation of the organic thin film solar cell is small, and it is not possible to ignore a temperature state of the organic thin film solar cell.

In step S3, detecting a temperature Twin of a window face to which the organic thin film solar cell is bonded is performed as follows. In a case in which the intensity of solar radiation detected in step S1 is 10 W/m² or more, a relationship between an open voltage Voc of the organic thin film solar cell and the temperature T₁ of the organic thin film solar cell becomes linear according to each intensity of solar radiation, and the temperature T₁ of the organic thin film solar cell is uniquely defined when the open voltage Voc is detected. According to the embodiment, the temperature T₁ of the organic thin film solar cell and the window face temperature Twin are approximately the same value, and it is possible to set the temperature T₁ of the organic thin film solar cell to the window face temperature Twin. The temperature T₁ of the organic thin film solar cell can be calculated from the following expression (1), by detecting the open voltage Voc of the organic thin film solar cell.

Voc=T₁×(nk/q)ln [(I_{L}/I₀)+1] Expression (1)

n: diode parameter, k: Boltzmann constant, q: elementary charge, I_{L}: photoelectric current associated with light irradiation, I₀: reverse saturation electromotive force, I: current in circuit, V: voltage, T₁: temperature of organic thin film solar cell

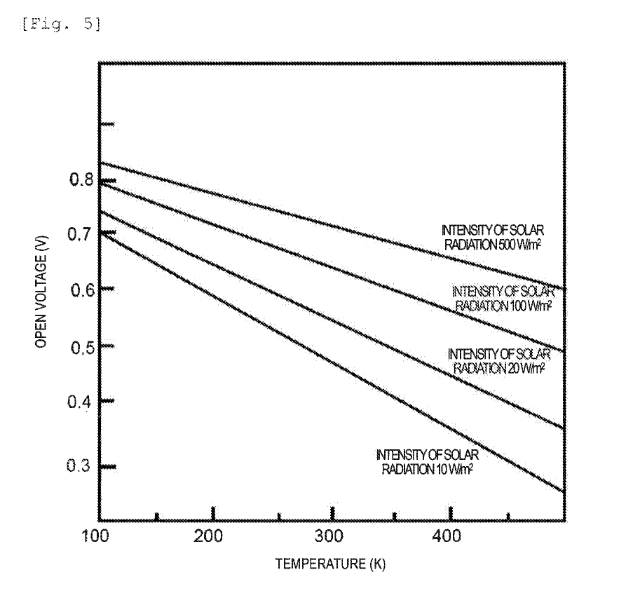

In addition, since the temperature and the open voltage value of the organic thin film solar cell denote a linear relationship according to the intensity of solar radiation, it is possible to regulate a temperature of the organic thin film solar cell by preparing a calibration curve corresponding to the intensity of solar radiation which is regulated in step S1, in addition to the calculation method of the temperature T₁ of the organic thin film solar cell in which the expression (1) is used. A relationship between the temperature and the open voltage value of the organic thin film solar cell is illustrated in FIG. 5.

In addition, since the open voltage is unstable in a case of a weak solar radiation condition of an intensity of solar radiation of 10 W/m² or less, the temperature T₁ of the organic thin film solar cell is not detected in the open voltage, and the room temperature Tr which is assumed in step S4 is set.

(Calculation of Heat Radiation Quantity Due to Convection and Radiation)

In step S5, a heat radiation quantity of a commodity to be irradiated due to convection and radiation is calculated. An intensity of solar radiation Igr which is input to the inside of a room by penetrating a glass face and the organic thin film solar cell is expressed, using an expression (2).

Igr=Io×α Expression (2)

α: total light transmittance of organic thin film solar cell

A commodity to be irradiated is configured of a light-shading commodity such as a blind, a solar radiation receiving object, or the like, such as floor, or a commodity, which are in the vicinity of a perimeter zone; however, in a case of the present invention, since most of solar radiation is absorbed in the organic thin film solar cell, there is no large deviation in calculation of a mean radiant temperature, even when radiation of only the organic thin film solar cell is taken into consideration. For this reason, heat quantities of convection and radiation may be obtained, using the temperature T₁ of the organic thin film solar cell which is obtained in steps S3 and S4.

A released heat quantity q_{ic} due to convection, which is released from the surface of the organic thin film solar cell can be obtained, using an expression (3).

q_{ic}=α_{ic}(T₁−Tr) Expression (3)

α_{ic}: indoor surface convective heat transfer coefficient, Tr: room temperature

Meanwhile, a released heat quantity qᵢₛ [kcal/m²] due to radiation is calculated, using the following expression (4).

qᵢₛ=q_{ic}+qᵢᵣ+q_{SR} Expression (4)

In expression (4), qᵢᵣ is a radiation exchange heat flow from a wall face between rooms which are adjacent to each other, and is regulated by a room temperature of an adjacent room, and a temperature of the own room. q_{SR} is a short wave length heat quantity which is configured of indoor lighting, or the like.

(Calculation of Mean Radiant Temperature)

A mean radiant temperature Trad [° C.] is calculated in step S6 using the following expression (5), by using the released heat quantity q_{ic} due to convection and the heat radiation quantity qᵢₛ due to radiation which are calculated in step S5.

qᵢₛ+q_{ic}=σT_{rad}⁴ Expression (5)

σ: Stefan Boltzmann coefficient

According to the embodiment, it is possible to obtain a temperature difference between a perimeter zone and a room temperature, that is, heat load of a perimeter zone, by calculating the mean radiant temperature T_{rad} in the perimeter zone. Accordingly, it is possible to perform an optimal air-conditioning control for balancing the heat load, and reduce energy consumption compared to a heat balancing state which has been controlled by using air-conditioning in an interior zone in the related art, or an intake air temperature of air-conditioning in a perimeter zone.

(Calculation of Predicted Mean Vote PMV)

According to the embodiment, it is possible to control heat balancing as a difference from a room temperature under an optimal condition, by calculating the mean radiant temperature in step S6. By adding a parameter in a human body detection environment to this effect, it is possible to perform a more detailed control. In step S7, the current PMV is calculated by using a well-known PMV calculation formula, a regression formula of these, or the like, using the estimated mean radiant temperature T_{rad} [° C.], a room temperature Tr [° C.] which is measured or set, a humidity H [%], an air velocity V [m/s], and a clothing amount C [clo] and an active amount M [met] of a person in a room.

(Heat Shutting-Off Effect and Power Generation Effect of Organic Thin Film Solar Cell)

In addition, it is possible to realize alleviation of an intensity of solar radiation which is input, and obtain a heat shutting-off property of an indoor heat quantity, since alleviation of solar radiation due to the heat shutting-off effect of the organic thin film solar cell, and a heat shutting-off effect associated with an improvement of a heat transmission coefficient are added, when the organic thin film solar cell is provided from an indoor side of the window opening portion. The organic thin film solar cell can shut off an intensity of solar radiation which is input inside, by absorbing or reflecting solar radiation. Part of solar radiation which is shut off is converted into energy which contributes to power generation, and a residual quantity becomes heat. Since a heat radiation quantity from the organic thin film solar cell can be calculated by expressions (2) to (4), it is possible to estimate the mean radiant temperature Trad including the heat radiation quantity of the organic thin film solar cell.

According to the embodiment, since the organic thin film solar cell generates power using input light on a window face, it is possible to perform a detailed air-conditioning control, by enabling producing of electric power using power generation, reducing of an indoor heat load using a heat shutting-off function of solar radiation, and successive detecting of an intensity of input light which is associated with power generation, and an window face temperature. In addition, since it is possible to successively detect heat load associated with a climate change in a perimeter zone, it is possible to relieve an air-conditioning mixing phenomenon in which heating of a perimeter zone in a winter season, and cooling of an interior zone are mixed. In addition, since it is possible to give comfort which is associated with solar radiation, it is effective in energy saving in lighting and dimming, or the like, which is caused by relieving of solar radiation conditions when being introduced to a perimeterless air-conditioning system such as air flow window (AFW) or double skin glass which is drastically spread in recent years, giving comfort in a perimeter zone, and an integration effect of solar radiation and lighting.

### Second Embodiment

In a second embodiment, a window face temperature is detected by using temperature dependence characteristics of a forward voltage as a diode of the organic thin film solar cell, even in a state in which there is no nighttime solar radiation, by using characteristics as a diode of the organic thin film solar cell.

(Configuration of System)

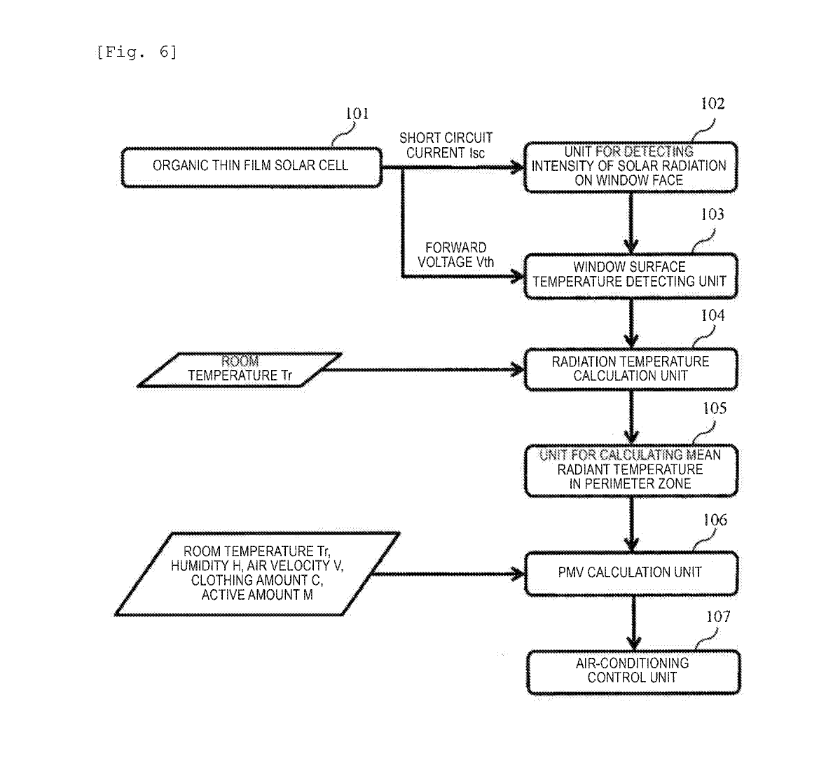

FIG. 6 is a functional block diagram which describes the second embodiment. The basic configuration is the same as that in FIG. 1, and a difference is that information which is input to the window surface temperature detecting unit 103 from the organic thin film solar cell 101 is changed to a forward voltage Vth.

(Specific Operation Method of System)

In the second embodiment, first, an intensity of solar radiation is detected, and the fact that solar radiation is extremely weak, and is a detection limit or less is confirmed. Subsequently, the forward voltage Vth is detected, and a temperature of the organic thin film solar cell, that is, a window face temperature is detected from Vth, by setting a method of detecting characteristics of the organic thin film solar cell to an electrical characteristics evaluation mode in a darkened state. Configurations after detecting the window face temperature are the same as those in the first embodiment.

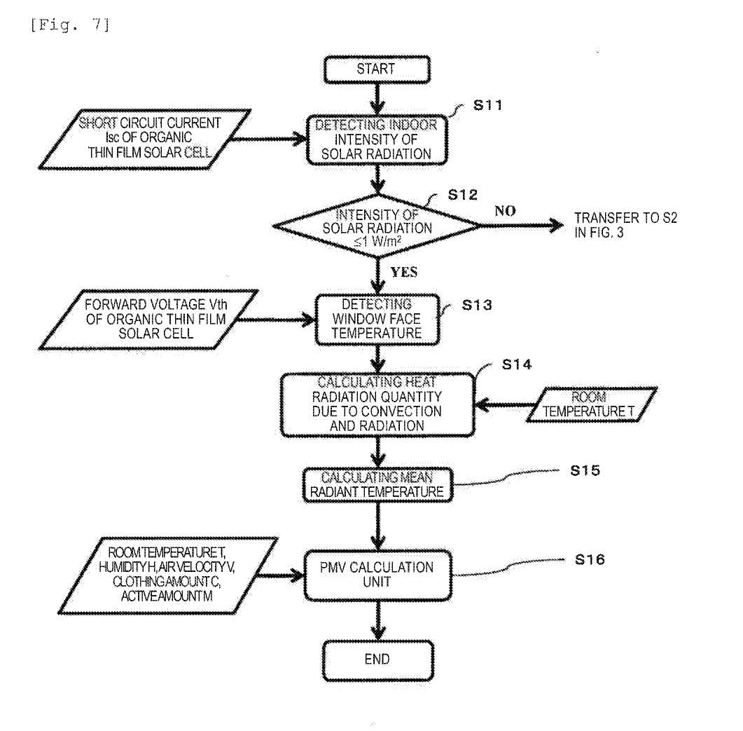

FIG. 7 is a flowchart which illustrates an operation procedure of the system in the embodiment.

(Specifying Nighttime Mode and Detecting Forward Voltage)

In the second embodiment, an intensity of solar radiation is detected, by detecting a short circuit current value of the organic thin film solar cell in step S11, similarly to the first embodiment. In step S12, the fact that solar radiation on the window face is extremely weak, or there is no solar radiation is confirmed. A standard when determining that there is no solar radiation is 1 W/m² or less, and in a case of matching the condition, the process proceeds to step S13, by setting a detecting mode of the organic thin film solar cell to the electrical characteristics evaluation mode in the darkened state. Meanwhile, in a case in which an intensity of solar radiation is larger than 1 W/m², the mean radiant temperature or PMV is calculated, using the method in the first embodiment, by transferring to step S2 in FIG. 3.

Subsequently, the forward voltage Vth of the organic thin film solar cell is measured in the electrical characteristics evaluation mode in the darkened state, in step S13. Vth can be denoted by a linear function which is illustrated in expression (6) with respect to a temperature.

Vth=Vth₀−α₀(T₁−Tth₀) Expression (6)

Here, Vth₀ is a forward voltage at a time of a reference temperature Tth₀, and α₀ is a diode temperature coefficient of the organic thin film solar cell.

Step S14 is a process of calculating a heat radiation quantity in the nighttime, step S15 is a process of calculating the mean radiant temperature, and step S16 is a process of calculating PMV, and these steps are the same as steps S5 to S7 in the first embodiment.

According to the second embodiment, it is possible to successively detect a window face temperature in the nighttime using electrical characteristics as a diode of the organic thin film solar cell. Since there is a large heat load in a perimeter zone due to a cold draft phenomenon on the window face in the nighttime, particularly in a winter time, and in the related art, it depends on a detecting temperature of an air conditioner, it is possible to remarkably alleviate a situation in which excessive power is consumed in order to alleviate heat load in the perimeter zone.

A case in which the invention is specifically performed will be described in the following example. In addition, the following example is an example for performing the invention, and does not limit the invention at all.

### Example 1

According to the first embodiment, a window face temperature is estimated from data of the organic thin film solar cell, and the mean radiant temperature is estimated therefrom. The organic thin film solar cell is provided on the window face, and is connected to an output control device (PCS) using wiring. A mechanism which can measure a short circuit current and an open voltage is provided in an inner circuit of PCS, and an intensity of solar radiation and the surface temperature of the organic thin film solar cell can be estimated, by providing a calibration curve which can detect a short circuit current thereof, an intensity of solar radiation from the open voltage, and the surface temperature of the organic thin film solar cell. Convection radiation, and radiant heat are estimated, using the surface temperature of the organic thin film solar cell, and the mean radiant temperature is calculated.

### Example 2

In the first embodiment, an air quantity, a clothing amount, a metabolic rate, a room temperature, and an interior humidity are input to the mean radiant temperature estimated using the example 1, and PMV is calculated.

### Example 3

Heat load in a perimeter zone in the nighttime is estimated, using the second embodiment. The organic thin film solar cell is provided on a window face, similarly to the example 1, and is connected to the output control device (PCS) using wiring. In a case of the nighttime in which solar radiation is remarkably small in PCS, or there is no solar radiation, a mode in which it is possible to detect diode characteristics of the organic thin film solar cell using an electronic load is set, and a forward threshold voltage Vth is detected from the diode characteristics. A temperature of the organic thin film solar cell is estimated from a value of Vth, convection radiation, and radiant heat are estimated, using the surface temperature of the organic thin film solar cell, and a mean radiant temperature is calculated.

### Example 4

In the second embodiment, an air quantity, a clothing amount, a metabolic rate, a room temperature, and an interior humidity are input to the mean radiant temperature estimated using the example 3, and PMV is calculated.

### Reference Example 1

In the first embodiment, a radiation thermometer (glove thermometer) which measures a mean radiant temperature is provided in the vicinity of the organic thin film solar cell on the interior side, and a measurement result of the radiation thermometer and an estimated result of the mean radiant temperature in the example 1 are compared to each other, in a state of the same configuration as that in the example 1.

### Reference Example 2

In the second embodiment, a radiation thermometer (glove thermometer) which measures a mean radiant temperature is provided in the vicinity of the organic thin film solar cell on the interior side, and a measurement result of the radiation thermometer and an estimated result of the mean radiant temperature in the example 3 are compared to each other, in a state of the same configuration as that in the example 3.

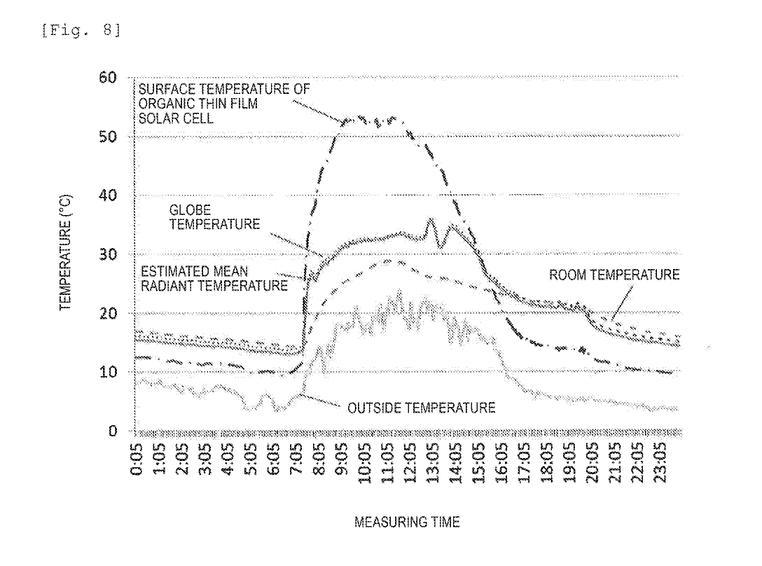

Results of the example 1 and the example 2 are illustrated in FIG. 8. The surface temperature of the organic thin film solar cell is detected based on the example 1. The organic thin film solar cell is driven so as to be balanced in heat shutting-off and power generation, based on absorbing of solar radiation. The organic thin film solar cell absorbs heat based on shielding of solar radiation, and the surface temperature rises. According to the invention, the surface temperature of the organic thin film solar cell can be detected corresponding to the open voltage. FIG. 8 illustrates an estimated result of the mean radiant temperature, by calculating a radiant heat quantity and a convection heat quantity from the surface temperature of the organic thin film solar cell which is detected from the open voltage. FIG. 8 illustrates the fact that the estimated mean radiant temperature becomes lower than the globe temperature which is measured in the reference example 1, by 0.3° C. to 0.7° C., and can be adopted as an index in an air-conditioning control without a problem. It can be assumed the reason of a temperature difference between the globe temperature and the mean radiant temperature which is assumed in the example 1 is that the difference is a value obtained when the mean radiant temperature estimated in the example 1 takes into consideration only the radiant heat and the convection heat of the organic thin film solar cell, and commodities at the periphery thereof are not taken into consideration. However, the reason why it is possible to perform a detection with a difference of 1.0° C. or less from a measured value of a globe temperature, using only the radiant heat and the convection heat of the organic thin film solar cell is that it is possible to absorb most of heat load of solar radiation, by shielding solar radiation of the organic thin film solar cell, and heat loads of other commodities are relatively small.

In FIG. 8, a performance result in a nighttime zone is also described, and the performance result corresponds to the example 3 and the reference example 2. The surface temperature of the organic thin film solar cell in the nighttime is close to an outside temperature since there is no solar radiation, and is located in an intermediate zone of a room temperature and an outside temperature. Accordingly, a mean radiant temperature in which both a window face of the organic thin film solar cell and a room temperature are taken into consideration is obtained, by taking into consideration the mean radiant temperature which is described in the second embodiment. As a result, the measured globe temperature is almost close to a room temperature, and according to a calculation result of the mean radiant temperature in the example 3, it is understood that the measured globe temperature is lower than the globe temperature by 0.5° C. to 0.7° C., and is lower than a room temperature by 1.0° C. to 2.0° C. Accordingly, according to the example 3, a radiant heat quantity and a convection heat quantity on the surface of the organic thin film solar cell are calculated from the surface temperature of the organic thin film solar cell, using a threshold voltage of the open voltage, and it is possible to estimate the mean radiant temperature which is configured of these radiant heat quantity, convection heat quantity, and a room temperature with good accuracy.

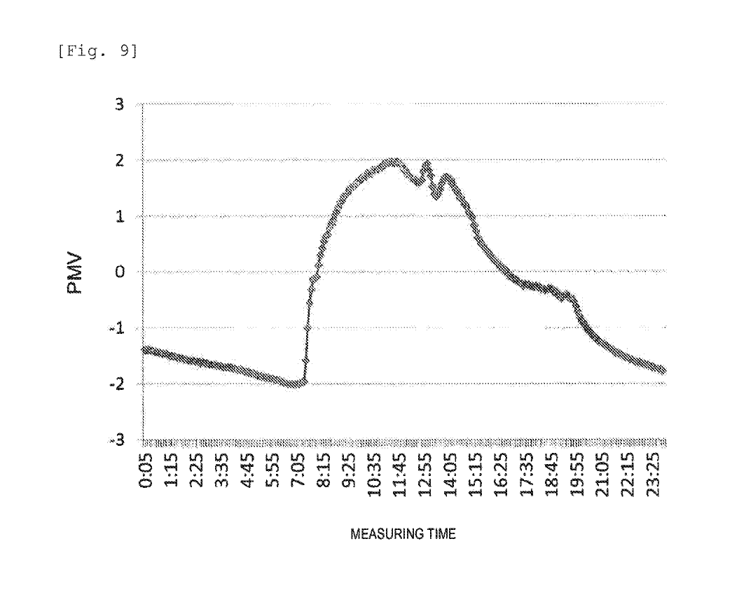

FIG. 9 illustrates a result of PMV which is obtained in the examples 2 and 4. It is possible to calculate PMV corresponding to the mean radiant temperature which is calculated based on the examples 1 and 3.

As described above, according to the estimating system of heat load in a perimeter zone, and the air-conditioning control system in the present invention, it is possible to provide a system in which an intensity of solar radiation and a window surface temperature are detected from information which is obtained at a time of power generation of the organic thin film solar cell, in a building in which the organic thin film solar cell is provided on a window face, and which can successively measure a temperature and humidity environment in a perimeter zone, by estimating the mean radiant temperature in a room. According to the system, it is possible to perform a successive optimal control with respect to an air-conditioning load in a perimeter zone, and realize energy saving in the entire building.

### REFERENCE SIGNS LIST

101: ORGANIC THIN FILM SOLAR CELL
102: UNIT FOR DETECTING INTENSITY OF SOLAR RADIATION ON WINDOW FACE
103: WINDOW SURFACE TEMPERATURE DETECTING UNIT
104: HEAT RADIATION QUANTITY CALCULATION UNIT
105: MEAN RADIANT TEMPERATURE CALCULATION UNIT
106: PMV CALCULATION UNIT
107: AIR-CONDITIONING CONTROL UNIT

1. An estimating system of heat load in a perimeter zone comprising:
a light-transmitting solar cell which is provided on a window face; and
heat load estimating means for estimating heat load in a perimeter zone, based on output characteristics of the solar cell,
wherein the heat load estimating means obtains an intensity of solar radiation from a window face and a temperature of the solar cell from a short circuit current value, and an open voltage value due to power generation of the solar cell, and calculates a mean radiant temperature in the perimeter zone using the intensity of solar radiation and the temperature of the solar cell.

2. The estimating system of heat load in a perimeter zone according to claim 1,
wherein the heat load estimating means calculates a PMV value using the calculated mean radiant temperature in the perimeter zone, a temperature, a humidity, and an air velocity in a room which are measured or set, and a clothing amount and an active amount of a person in a room.

3. The estimating system of heat load in a perimeter zone according to claim 1,
wherein the heat load estimating means detects a temperature of the solar cell by detecting a forward voltage which is characteristics of a diode of the solar cell, in nighttime in which there is no solar radiation.

4. The estimating system of heat load in a perimeter zone according to claim 1,
wherein the solar cell is an organic thin film solar cell.

5. An air-conditioning control system comprising:
a light-transmitting solar cell which is provided on a window face;
heat load estimating means for estimating heat load in a perimeter zone based on output characteristics of the solar cell; and
an air-conditioning control unit which performs an air-conditioning control based on heat load which is estimated in the heat load estimating means,
wherein the heat load estimating means obtains an intensity of solar radiation from a window face and a temperature of the solar cell, from a short circuit current value and an open voltage value due to power generation of the solar cell, and calculates a mean radiant temperature in the perimeter zone using the intensity of solar radiation and the temperature of the solar cell.

6. The air-conditioning control system according to claim 5,
wherein the heat load estimating means calculates a PMV value using the calculated mean radiant temperature in the perimeter zone, a temperature, a humidity, and an air velocity in a room which are measured or set, and a clothing amount and an active amount of a person in a room.

7. The air-conditioning control system according to claim 5,
wherein the heat load estimating means detects a temperature of the solar cell by detecting a forward voltage which is characteristics of a diode of the solar cell, in nighttime in which there is no solar radiation.

8. The air-conditioning control system according to claim 5,
wherein the solar cell is an organic thin film solar cell.
